(19) United States
(12) Patent Application Publication
(10) Pub. No.: US 2024/0384148 A1
(43) Pub. Date: Nov. 21, 2024

(54) MANUFACTURING PROCESS FOR COILED GRAPHENE HEAT DISSIPATION FILM MATERIAL

(71) Applicant: ZHEJIAN DAOMING SUPERCONDUCTOR TECHNOLOGY CO., LTD., Jinhua, Zhejiang Province (CN)

(72) Inventors: Hongchun WANG, Jinhua, Zhejiang Province (CN); Zehui ZHANG, Jinhua, Zhejiang Province (CN); Feng HU, Jinhua, Zhejiang Province (CN); Likao WU, Jinhua, Zhejiang Province (CN); Pei XU, Jinhua, Zhejiang Province (CN); Zhuang LIU, Jinhua, Zhejiang Province (CN)

(73) Assignee: ZHEJIAN DAOMING SUPERCONDUCTOR TECHNOLOGY CO., LTD., Jinhua, Zhejiang Province (CN)

(21) Appl. No.: 18/704,092

(22) PCT Filed: Dec. 8, 2022
(86) PCT No.: PCT/CN2022/137424

§ 371 Date: Apr. 24, 2024

(30) Foreign Application Priority Data
Mar. 4, 2022 (CN) 202210209571.0

(51) Int. Cl. C09K 5/14; C01B 32/198

(52) U.S. Cl. CPC C09K 5/14; C01B 32/198

(57) ABSTRACT

Provided is a manufacturing process for a coiled graphene heat dissipation film material, comprising the following preparation steps: S1: preparing a graphene oxide dispersion using a graphene oxide cake material; S2: homogenizing and defoaming; S3: coating a substrate with the graphene oxide slurry via a coating machine, subjecting the substrate to stripping and slitting to give a pretreated graphene film, and coiling the film to form a tightly coiled pretreated graphene film material; S4: subjecting the tightly coiled pretreated graphene film material to loosening treatment in a reverse coiling mechanism to give a loosely coiled pretreated graphene film material; S5: subjecting the loosely coiled pretreated graphene film material to low-temperature treatment, carbonization treatment, and graphitization treatment to prepare a coiled graphene foam film material; and S6: subjecting the coiled graphene foam film material to single-layer rolling or multi-layer rolling to prepare the coiled graphene heat dissipation material.

### TECHNICAL FIELD

The present invention relates to the field of graphene technology, in particular to a manufacturing process for a coiled graphene heat dissipation film material.

### BACKGROUND

Heat conduction and heat dissipation films have significant applications in many fields such as electronics, communication, aviation, national defense, and military industry today. Among them, graphene heat dissipation films are widely used and quickly replace conventional materials due to their advantages such as high thermal conductivity, light weight, and small volume.

At present, mainstream preparation methods for graphene heat dissipation films include a coating heat treatment method. A process flow of the coating heat treatment method includes processes of slurry preparation, coating, impurity removal, heat treatment, rolling, etc., where the film material is cut into sheets for subsequent treatment. However, the preparation process is not continuous and can only prepare graphene sheets, resulting in high subsequent die-cutting costs, cumbersome production processes, and high labor costs, which cannot meet the requirements of industrial automation production and is not conducive to the promotion and application of graphene heat dissipation films.

Based on the above situation, continuous preparation processes for graphene heat dissipation films suitable for industrial production need to be optimized.

### SUMMARY

The present invention provides a novel manufacturing process for a coiled graphene heat dissipation film material in response to the shortcomings of high die-cutting costs, cumbersome production processes, high labor costs, and inability to meet the requirements of industrial automation production due to the fact that preparation processes for graphene heat dissipation films can prepare only graphene sheets in existing technologies.

In order to solve the above technical problems, the present invention is implemented through the following technical solution:

A manufacturing process for a coiled graphene heat dissipation film material includes the following preparation steps:
S1: dispersing a graphene oxide cake material in deionized water to prepare a grapheneoxide dispersion with a weight percentage of 3%-6%;
S2: slowly pouring ammonia water into the graphene oxide dispersion until a pH value of the graphene oxide dispersion reaches 6-10, and then performing homogenization and defoaming treatment to obtain a graphene oxide slurry with a viscosity of 15000-60000 Pa/s, where a particle size in the graphene oxide slurry is controlled within a range of 0.5 μm-3 μm;
S3: taking a base material, coating the base material with the graphene oxide slurry through a coating machine while controlling a coating thickness to 0.1-0.5 mm, then drying in an environment of 40° C.-85° C., peeling, slitting to obtain a pretreated graphene film, and coiling through a coiling mechanism at a speed of 0.5-2.5 m/min and a tension controlled at 20-200 N to form a tight coiled pretreated graphene film material;
S4: placing the tight coiled pretreated graphene film material in an uncoiling mechanism for uncoiling at a speed of less than 30 m/min and a tension controlled below 30 N to obtain a loose coiled pretreated graphene film material with preset tightness;
S5: placing the loose coiled pretreated graphene film material in an environment of 200° C.-450° C. for low-temperature treatment for 12-200 h, then placing in an environment of not more than 1400° C. for carbonization for 10-50 h, and finally placing in an environment of not more than 3200° C. for graphitization for 10-50 h to obtain a coiled graphene foam film material; and
S6: performing single-layer rolling or multi-layer rolling on the coiled graphene foam film material by an extrusion roller under pressure of 1 T-5 T to obtain a coiled graphene heat dissipation material with a thermal conductivity of 800-2000 w·m/K.

In step S1, the weight percentage of the graphene oxide dispersion is controlled to facilitate subsequent viscosity control.

In step S2, because graphene oxide GO is easily reduced and agglomerates when the pH value of the graphene oxide dispersion is more than 11, the ammonia water is added in the present invention to adjust the pH value to the range of 6-10, and the graphene oxide with negative charges and the homogenization and defoaming treatment can significantly improve the dispersion effect of the graphene oxide dispersion.

In addition, the homogenization treatment can break up large particles in the graphene oxide dispersion into small particles, thereby obtaining a graphene oxide dispersion with uniform particle size and excellent dispersion effect, which also helps to improve the stability of the product.

In step S4, the graphene film expands and releases heat and a large amount of gas in the high-temperature treatment process; and by uncoiling, there is an appropriate gap between adjacent film layers of the loose coiled pretreated graphene film material, which is conducive to improving heat dissipation and air permeability.

In step S5, the low-temperature treatment can eliminate water and most oxygen-containing functional groups to prevent furnace explosion; and the carbonization and graphitization can improve thermal conductivity (thermal diffusion coefficient).

In step S6, the rolling can increase the density and thermal conductivity of the coiled graphene heat dissipation material.

The manufacturing process of the present invention can prepare a continuous stably dispersed coiled graphene heat dissipation film material with good process stability, significantly improves production efficiency, and reduces costs.

As a preferred option, in the foregoing manufacturing process for a coiled graphene heat dissipation film material, in step S4, coating pre-stacking treatment is performed by a pre-stacking mechanism on the tight coiled pretreated graphene film material before uncoiling, and steps of the coating pre-stacking treatment are as follows:
S4-1: mounting multiple coils of the tight coiled pretreated graphene film material on an uncoiling roller group, where the pre-stacking mechanism includes the uncoiling roller group, a rubber tube group, and a coiling roller, a speed of the uncoiling roller group is set to 1-5 m/min, a speed of the coiling roller is set to 1-5 m/min, and a coiling tension is controlled to 5-500 N; and
S4-2: charging the rubber tube group with an adhesive, applying the adhesive to a surface of the tight coiled pretreated graphene film material uniformly by the rubber tube group to form an adhesive layer, and then drying in an environment of 20° C.-60° C. for 3-48 min, where a dry thickness of the adhesive layer is 2-20 μm.

To prepare a thicker coiled graphene material and avoid layering during rolling,
in step S4-1, the pre-stacking mechanism can stack multiple coils of the tight coiled pretreated graphene film material to rapidly increase the thickness of the coiled material; and
in step S4-2, the adhesive can bond the multiple coils of the tight coiled pretreated graphene film material to avoid layering while increasing the thickness.

As a preferred option, in the foregoing manufacturing process for a coiled graphene heat dissipation film material, the adhesive includes one or more of epoxy resin, phenolic resin, acrylic resin, polyvinyl alcohol resin, polyethylene glycol water-based resin, and polyurethane resin.

The adhesive made of the above material(s) in the present invention has excellent bonding effect, and ensures the bonding effect of the tight coiled pretreated graphene film material.

As a preferred option, in the foregoing manufacturing process for a coiled graphene heat dissipation film material, the tight coiled pretreated graphene film material after the coating pre-stacking treatment is drilled with micropores having a diameter of 10-500 μm and a distribution density of 2000-100000/m².

The tight coiled pretreated graphene film material is drilled to facilitate the discharge of water and gas such as carbon dioxide during high-temperature treatment, so that the film material is foamed uniformly to facilitate subsequent rolling and exhaust.

As a preferred option, in the foregoing manufacturing process for a coiled graphene heat dissipation film material, the drilled tight coiled pretreated graphene film material is cured in an environment of 50° C.-150° C. for 3-10 h.

The curing process can dry the pre-stacking adhesive thoroughly and remove some water and oxygen-containing functional groups to prevent furnace explosion during the high-temperature treatment.

As a preferred option, in the foregoing manufacturing process for a coiled graphene heat dissipation film material, in step S6, the multi-layer rolling adopts a post-stacking rolling mechanism, the post-stacking rolling mechanism includes two to five traction rollers and a coiling round roller, a speed of the traction rollers is set to 1-5 m/min, a speed of the coiling round roller is set to 1-5 m/min, and a coiling tension is controlled to 5-200 N.

The post-stacking rolling can roll multiple layers of graphene films together to prepare graphene heat dissipation films with different thicknesses.

As a preferred option, in the foregoing manufacturing process for a coiled graphene heat dissipation film material, the tight coiled pretreated graphene film material has a width of 10 cm-70 cm and a length of 30 m-200 m.

As a preferred option, in the foregoing manufacturing process for a coiled graphene heat dissipation film material, a gap D between adjacent film layers in the loose coiled pretreated graphene film material is two to nine times a thickness of the film layers.

If the gap D in the loose coiled pretreated graphene film material is too small, heat dissipation and gas emission are difficult, and furnace explosion is prone to occur. If the gap D is too large, the high-temperature loading capacity is greatly reduced, and the cost is increased. Therefore, the above parameter selected in the present invention can be suitable for large-scale industrial production.

As a preferred option, in the foregoing manufacturing process for a coiled graphene heat dissipation film material, in the homogenization process of step S2, the homogenization pressure is 30-150 MPa, and the temperature is controlled at 10° C.-50° C.; and in the defoaming process, the degree of vacuum is maintained at 1 KPa-10 KPa.

The homogenization process of the present invention adopts the homogenization pressure and temperature of the above parameters, which can better control the particle size uniformity of the graphene oxide slurry, thereby obtaining the graphene oxide slurry with a particle size of 0.5 μm-3 μm and enabling the final product to obtain optimal thermal conductivity.

As a preferred option, in the foregoing manufacturing process for a coiled graphene heat dissipation film material, in step S6, the multi-layer rolling includes an uncoiling stage, a first precision pressing stage, a second precision pressing stage, a third precision pressing stage, a fourth precision pressing stage, and a coiling stage; each of the uncoiling stage and the coiling stage is provided with a tension control unit and a tension amplifier; each of the first precision pressing stage, the second precision pressing stage, the third precision pressing stage, and the fourth precision pressing stage is provided with a pressure control unit, a pressure sensor, a linear speed control unit, and a speedometer; and the tension control unit, the pressure control unit, and the linear speed control unit are all connected to a PLC central processing unit.

The multi-layer rolling is used for preparing coiled graphene heat dissipation film materials with different thicknesses, and even ultra-thick (25 μm or more) coiled graphene heat dissipation film materials. The thicker coiled material indicates more critical rolling pressure and speed, which determine the quality of the coiled material.

The multi-layer rolling is divided into the first precision pressing stage, the second precision pressing stage, the third precision pressing stage, and the fourth precision pressing stage, which not only fully exhaust the coiled graphene foam film material, but also efficiently increase the density of the coiled material, and significantly improve thermal conductivity. The multi-stage rolling can also improve automation efficiency and facilitate continuous production to improve efficiency.

### BRIEF DESCRIPTION OF THE DRAWINGS

FIG. 1 is a schematic structural diagram of a tight coiled pretreated graphene film material in the present invention;

FIG. 2 is a schematic structural diagram of a loose coiled pretreated graphene film material in the present invention;

FIG. 3 is a schematic structural diagram of a pre-stacking mechanism in the present invention;

FIG. 4 is a schematic structural diagram of a post-stacking rolling mechanism in the present invention; and

FIG. 5 is a schematic flowchart of multi-layer rolling in the present invention.

### DETAILED DESCRIPTION OF THE EMBODIMENTS

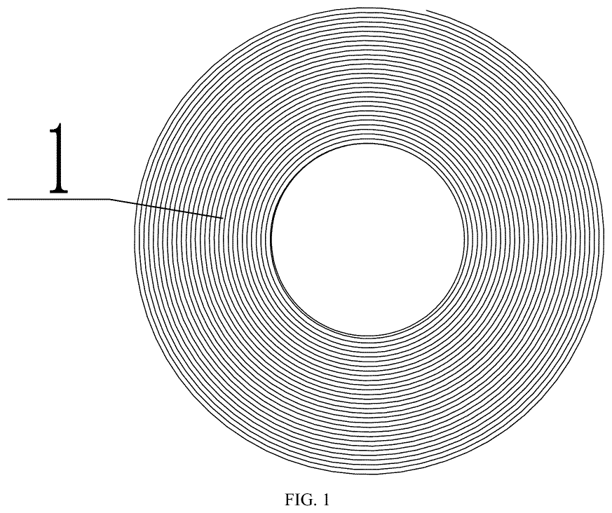

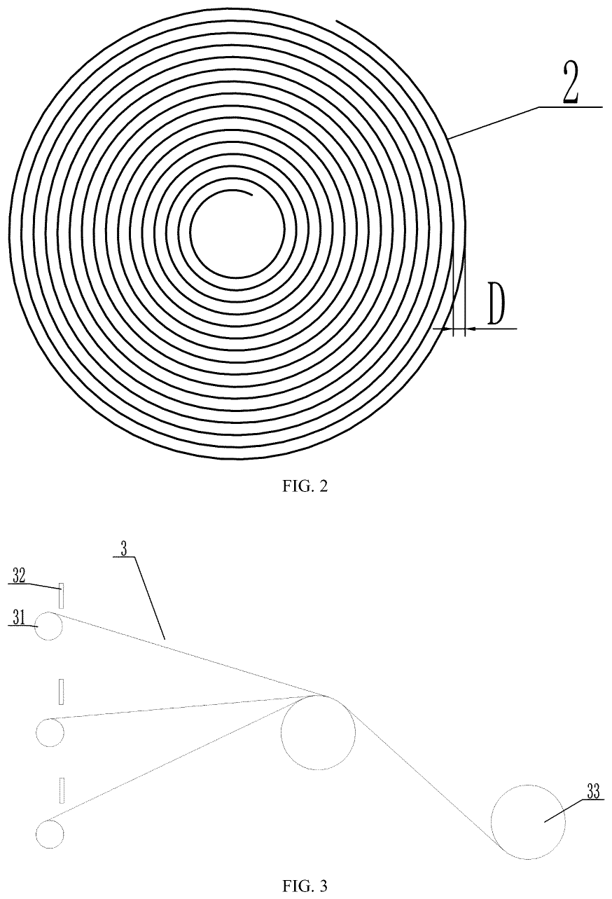

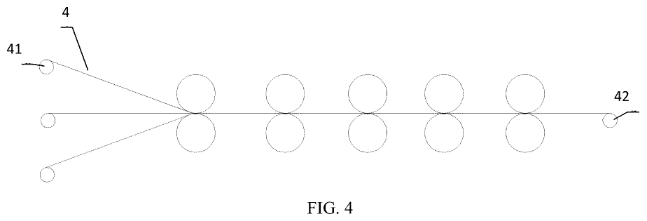

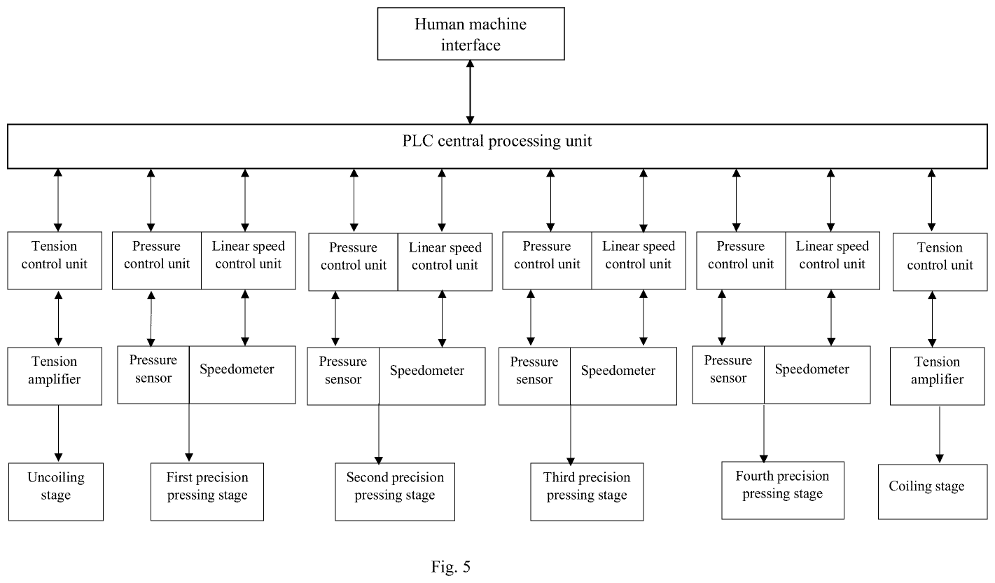

The present invention will be further described in detail below in conjunction with FIGS. 1-5 and specific implementations, but is not limited thereto.

### Embodiment 1

A manufacturing process for a coiled graphene heat dissipation film material includes the following preparation steps:
S1: dispersing a graphene oxide cake material in deionized water to prepare a graphene oxide dispersion with a weight percentage of 3%;
S2: slowly pouring ammonia water into the graphene oxide dispersion until a pH value of the graphene oxide dispersion reaches 6, and then performing homogenization and defoaming treatment to obtain a graphene oxide slurry with a viscosity of 15000 Pa/s, where a particle size in the graphene oxide slurry is controlled within a range of 0.5 μm-3 μm;
S3: taking a base material, coating the base material with the graphene oxide slurry through a coating machine while controlling a coating thickness to 0.1 mm, then drying in a 40° C. environment, peeling, slitting to obtain a pretreated graphene film, and coiling through a coiling mechanism at a speed of 0.5 m/min and a tension controlled at 20 N to form a tight coiled pretreated graphene film material 1;
S4: placing the tight coiled pretreated graphene film material 1 in an uncoiling mechanism for uncoiling at a speed of less than 30 m/min and a tension controlled below 30 N to obtain a loose coiled pretreated graphene film material 2 with preset tightness;
S5: placing the loose coiled pretreated graphene film material 2 in an environment of 200° C. for low-temperature treatment for 12 h, then placing in an environment of not more than 1400° C. for carbonization for 10 h, and finally placing in an environment of not more than 3200° C. for graphitization for 10 h to obtain a coiled graphene foam film material; and
S6: performing single-layer rolling or multi-layer rolling on the coiled graphene foam film material by an extrusion roller under pressure of 1 T to obtain a coiled graphene heat dissipation material with a thermal conductivity of 800 w·m/K.

As a preferred option, in step S4, coating pre-stacking treatment is performed by a pre-stacking mechanism 3 on the tight coiled pretreated graphene film material 1 before uncoiling, and steps of the coating pre-stacking treatment are as follows:
S4-1: mounting multiple coils of the tight coiled pretreated graphene film material 1 on an uncoiling roller group 31, where the pre-stacking mechanism 3 includes the uncoiling roller group 31, a rubber tube group 32, and a coiling roller 33, a speed of the uncoiling roller group 31 is set to 1 m/min, a speed of the coiling roller 33 is set to 1 m/min, and a coiling tension is controlled to 5 N; and
S4-2: charging the rubber tube group 32 with an adhesive, applying the adhesive to a surface of the tight coiled pretreated graphene film material 1 uniformly by the rubber tube group 32 to form an adhesive layer, and then drying in an environment of 20° C. for 3 min, where a dry thickness of the adhesive layer is 2 μm.

As a preferred option, the adhesive includes one or more of epoxy resin, phenolic resin, acrylic resin, polyvinyl alcohol resin, polyethylene glycol water-based resin, and polyurethane resin.

As a preferred option, the tight coiled pretreated graphene film material 1 after the coating pre-stacking treatment is drilled with micropores having a diameter of 10 μm and a distribution density of 2000/m².

As a preferred option, the drilled tight coiled pretreated graphene film material 1 is cured in an environment of 50° C. for 3 h.

As a preferred option, in step S6, the multi-layer rolling adopts a post-stacking rolling mechanism 4, the post-stacking rolling mechanism 4 includes two traction rollers 41 and a coiling round roller 42, a speed of the traction rollers 41 is set to 1 m/min, a speed of the coiling round roller 42 is set to 1 m/min, and a coiling tension is controlled to 5 N.

As a preferred option, the tight coiled pretreated graphene film material 1 has a width of 10 cm and a length of 30 m.

As a preferred option, a gap D between adjacent film layers in the loose coiled pretreated graphene film material 2 is twice a thickness of the film layers.

As a preferred option, in the homogenization process of step S2, the homogenization pressure is 30 MPa, and the temperature is controlled at 10° C.; and in the defoaming process, the degree of vacuum is maintained at 1 KPa.

As a preferred option, in step S6, the multi-layer rolling includes an uncoiling stage, a first precision pressing stage, a second precision pressing stage, a third precision pressing stage, a fourth precision pressing stage, and a coiling stage; each of the uncoiling stage and the coiling stage is provided with a tension control unit and a tension amplifier; each of the first precision pressing stage, the second precision pressing stage, the third precision pressing stage, and the fourth precision pressing stage is provided with a pressure control unit, a pressure sensor, a linear speed control unit, and a speedometer; and the tension control unit, the pressure control unit, and the linear speed control unit are all connected to a PLC central processing unit.

### Embodiment 2

A manufacturing process for a coiled graphene heat dissipation film material includes the following preparation steps:
S1: dispersing a graphene oxide cake material in deionized water to prepare a graphene oxide dispersion with a weight percentage of 6%;
S2: slowly pouring ammonia water into the graphene oxide dispersion until a pH value of the graphene oxide dispersion reaches 10, and then performing homogenization and defoaming treatment to obtain a graphene oxide slurry with a viscosity of 60000 Pa/s, where a particle size in the graphene oxide slurry is controlled within a range of 0.5 μm-3 μm;
S3: taking a base material, coating the base material with the graphene oxide slurry through a coating machine while controlling a coating thickness to 0.5 mm, then drying in a 85° C. environment, peeling, slitting to obtain a pretreated graphene film, and coiling through a coiling mechanism at a speed of 2.5 m/min and a tension controlled at 200 N to form a tight coiled pretreated graphene film material 1;
S4: placing the tight coiled pretreated graphene film material 1 in an uncoiling mechanism for uncoiling at a speed of less than 30 m/min and a tension controlled below 30 N to obtain a loose coiled pretreated graphene film material 2 with preset tightness;
S5: placing the loose coiled pretreated graphene film material 2 in an environment of 450° C. for low-temperature treatment for 200 h, then placing in an environment of not more than 1400° C. for carbonization for 50 h, and finally placing in an environment of not more than 3200° C. for graphitization for 50 h to obtain a coiled graphene foam film material; and
S6: performing single-layer rolling or multi-layer rolling on the coiled graphene foam film material by an extrusion roller under pressure of 5 T to obtain a coiled graphene heat dissipation material with a thermal conductivity of 2000 w·m/K.

As a preferred option, in step S4, coating pre-stacking treatment is performed by a pre-stacking mechanism 3 on the tight coiled pretreated graphene film material 1 before uncoiling, and steps of the coating pre-stacking treatment are as follows:
S4-1: mounting multiple coils of the tight coiled pretreated graphene film material 1 on an uncoiling roller group 31, where the pre-stacking mechanism 3 includes the uncoiling roller group 31, a rubber tube group 32, and a coiling roller 33, a speed of the uncoiling roller group 31 is set to 5 m/min, a speed of the coiling roller 33 is set to 5 m/min, and a coiling tension is controlled to 500 N; and
S4-2: charging the rubber tube group 32 with an adhesive, applying the adhesive to a surface of the tight coiled pretreated graphene film material 1 uniformly by the rubber tube group 32 to form an adhesive layer, and then drying in an environment of 60° C. for 48 min, where a dry thickness of the adhesive layer is 20 μm.

As a preferred option, the adhesive includes one or more of epoxy resin, phenolic resin, acrylic resin, polyvinyl alcohol resin, polyethylene glycol water-based resin, and polyurethane resin.

As a preferred option, the tight coiled pretreated graphene film material 1 after the coating pre-stacking treatment is drilled with micropores having a diameter of 500 μm and a distribution density of 100000/m².

As a preferred option, the drilled tight coiled pretreated graphene film material 1 is cured in an environment of 150° C. for 10 h.

As a preferred option, in step S6, the multi-layer rolling adopts a post-stacking rolling mechanism 4, the post-stacking rolling mechanism 4 includes five traction rollers 41 and a coiling round roller 42, a speed of the traction rollers 41 is set to 5 m/min, a speed of the coiling round roller 42 is set to 5 m/min, and a coiling tension is controlled to 200 N.

As a preferred option, the tight coiled pretreated graphene film material 1 has a width of 70 cm and a length of 200 m.

As a preferred option, a gap D between adjacent film layers in the loose coiled pretreated graphene film material 2 is nine times a thickness of the film layers.

As a preferred option, in the homogenization process of step S2, the homogenization pressure is 150 MPa, and the temperature is controlled at 50° C.; and in the defoaming process, the degree of vacuum is maintained at 10 KPa.

As a preferred option, in step S6, the multi-layer rolling includes an uncoiling stage, a first precision pressing stage, a second precision pressing stage, a third precision pressing stage, a fourth precision pressing stage, and a coiling stage; each of the uncoiling stage and the coiling stage is provided with a tension control unit and a tension amplifier; each of the first precision pressing stage, the second precision pressing stage, the third precision pressing stage, and the fourth precision pressing stage is provided with a pressure control unit, a pressure sensor, a linear speed control unit, and a speedometer; and the tension control unit, the pressure control unit, and the linear speed control unit are all connected to a PLC central processing unit.

### Embodiment 3

A manufacturing process for a coiled graphene heat dissipation film material includes the following preparation steps:
S1: dispersing a graphene oxide cake material in deionized water to prepare a graphene oxide dispersion with a weight percentage of 4%;
S2: slowly pouring ammonia water into the graphene oxide dispersion until a pH value of the graphene oxide dispersion reaches 8, and then performing homogenization and defoaming treatment to obtain a graphene oxide slurry with a viscosity of 35000 Pa/s, where a particle size in the graphene oxide slurry is controlled within a range of 0.5 μm-3 μm;
S3: taking a base material, coating the base material with the graphene oxide slurry through a coating machine while controlling a coating thickness to 0.3 mm, then drying in a 65° C. environment, peeling, slitting to obtain a pretreated graphene film, and coiling through a coiling mechanism at a speed of 1.5 m/min and a tension controlled at 100 N to form a tight coiled pretreated graphene film material 1;
S4: placing the tight coiled pretreated graphene film material 1 in an uncoiling mechanism for uncoiling at a speed of less than 30 m/min and a tension controlled below 30 N to obtain a loose coiled pretreated graphene film material 2 with preset tightness;
S5: placing the loose coiled pretreated graphene film material 2 in an environment of 350° C. for low-temperature treatment for 100 h, then placing in an environment of not more than 1400° C. for carbonization for 30 h, and finally placing in an environment of not more than 3200° C. for graphitization for 30 h to obtain a coiled graphene foam film material; and
S6: performing single-layer rolling or multi-layer rolling on the coiled graphene foam film material by an extrusion roller under pressure of 3 T to obtain a coiled graphene heat dissipation material with a thermal conductivity of 1400 w·m/K.

As a preferred option, in step S4, coating pre-stacking treatment is performed by a pre-stacking mechanism 3 on the tight coiled pretreated graphene film material 1 before uncoiling, and steps of the coating pre-stacking treatment are as follows:
S4-1: mounting multiple coils of the tight coiled pretreated graphene film material 1 on an uncoiling roller group 31, where the pre-stacking mechanism 3 includes the uncoiling roller group 31, a rubber tube group 32, and a coiling roller 33, a speed of the uncoiling roller group 31 is set to 3 m/min, a speed of the coiling roller 33 is set to 3 m/min, and a coiling tension is controlled to 250 N; and
S4-2: charging the rubber tube group 32 with an adhesive, applying the adhesive to a surface of the tight coiled pretreated graphene film material 1 uniformly by the rubber tube group 32 to form an adhesive layer, and then drying in an environment of 40° C. for 30 min, where a dry thickness of the adhesive layer is 10 μm.

As a preferred option, the adhesive includes one or more of epoxy resin, phenolic resin, acrylic resin, polyvinyl alcohol resin, polyethylene glycol water-based resin, and polyurethane resin.

As a preferred option, the tight coiled pretreated graphene film material 1 after the coating pre-stacking treatment is drilled with micropores having a diameter of 300 μm and a distribution density of 50000/m².

As a preferred option, the drilled tight coiled pretreated graphene film material 1 is cured in an environment of 100° C. for 6 h.

As a preferred option, in step S6, the multi-layer rolling adopts a post-stacking rolling mechanism 4, the post-stacking rolling mechanism 4 includes three traction rollers 41 and a coiling round roller 42, a speed of the traction rollers 41 is set to 3 m/min, a speed of the coiling round roller 42 is set to 3 m/min, and a coiling tension is controlled to 100 N.

As a preferred option, the tight coiled pretreated graphene film material 1 has a width of 40 cm and a length of 100 m.

As a preferred option, a gap D between adjacent film layers in the loose coiled pretreated graphene film material 2 is five times a thickness of the film layers.

As a preferred option, in the homogenization process of step S2, the homogenization pressure is 90 MPa, and the temperature is controlled at 30° C.; and in the defoaming process, the degree of vacuum is maintained at 5 KPa.

As a preferred option, in step S6, the multi-layer rolling includes an uncoiling stage, a first precision pressing stage, a second precision pressing stage, a third precision pressing stage, a fourth precision pressing stage, and a coiling stage; each of the uncoiling stage and the coiling stage is provided with a tension control unit and a tension amplifier; each of the first precision pressing stage, the second precision pressing stage, the third precision pressing stage, and the fourth precision pressing stage is provided with a pressure control unit, a pressure sensor, a linear speed control unit, and a speedometer; and the tension control unit, the pressure control unit, and the linear speed control unit are all connected to a PLC central processing unit.

In summary, described above are only the preferred embodiments of the present invention. Any changes and modifications made within the scope of the present invention shall fall into the scope of the present invention.

What is claimed is:

1. A manufacturing process for a coiled graphene heat dissipation film material, comprising the following preparation steps:
S1: dispersing a graphene oxide cake material in deionized water to prepare a graphene oxide dispersion with a weight percentage of 3%-6%;
S2: slowly pouring ammonia water into the graphene oxide dispersion until a pH value of the graphene oxide dispersion reaches 6-10, and then performing homogenization and defoaming treatment to obtain a graphene oxide slurry with a viscosity of 15000-60000 Pa/s, wherein a particle size in the graphene oxide slurry is controlled within a range of 0.5 μm-3 μm;
S3: taking a base material, coating the base material with the graphene oxide slurry through a coating machine while controlling a coating thickness to 0.1-0.5 mm, then drying in an environment of 40° C.-85° C., peeling, slitting to obtain a pretreated graphene film, and coiling through a coiling mechanism at a speed of 0.5-2.5 m/min and a tension controlled at 20-200 N to form a tight coiled pretreated graphene film material (1);
S4: placing the tight coiled pretreated graphene film material (1) in an uncoiling mechanism for uncoiling at a speed of less than 30 m/min and a tension controlled below 30 N to obtain a loose coiled pretreated graphene film material (2) with preset tightness;
S5: placing the loose coiled pretreated graphene film material (2) in an environment of 200° C.-450° C. for low-temperature treatment for 12-200 h, then placing in an environment of not more than 1400° C. for carbonization for 10-50 h, and finally placing in an environment of not more than 3200° C. for graphitization for 10-50 h to obtain a coiled graphene foam film material; and
S6: performing single-layer rolling or multi-layer rolling on the coiled graphene foam film material by an extrusion roller under pressure of 1 T-5 T to obtain a coiled graphene heat dissipation material with a thermal conductivity of 800-2000 w·m/K.

2. The manufacturing process for a coiled graphene heat dissipation film material according to claim 1, wherein in step S4, coating pre-stacking treatment is performed by a pre-stacking mechanism (3) on the tight coiled pretreated graphene film material (1) before uncoiling, and steps of the coating pre-stacking treatment are as follows:
S4-1: mounting multiple coils of the tight coiled pretreated graphene film material (1) on an uncoiling roller group (31), wherein the pre-stacking mechanism (3) comprises the uncoiling roller group (31), a rubber tube group (32), and a coiling roller (33), a speed of the uncoiling roller group (31) is set to 1-5 m/min, a speed of the coiling roller (33) is set to 1-5 m/min, and a coiling tension is controlled to 5-500 N; and
S4-2: charging the rubber tube group (32) with an adhesive, applying the adhesive to a surface of the tight coiled pretreated graphene film material (1) uniformly by the rubber tube group (32) to form an adhesive layer, and then drying in an environment of 20° C.-60° C. for 3-48 min, wherein a dry thickness of the adhesive layer is 2-20 μm.

3. The manufacturing process for a coiled graphene heat dissipation film material according to claim 2, wherein the adhesive comprises one or more of epoxy resin, phenolic resin, acrylic resin, polyvinyl alcohol resin, polyethylene glycol water-based resin, and polyurethane resin.

4. The manufacturing process for a coiled graphene heat dissipation film material according to claim 2, wherein the tight coiled pretreated graphene film material (1) after the coating pre-stacking treatment is drilled with micropores having a diameter of 10-500 μm and a distribution density of 2000-100000/m².

5. The manufacturing process for a coiled graphene heat dissipation film material according to claim 4, wherein the drilled tight coiled pretreated graphene film material (1) is cured in an environment of 50° C.-150° C. for 3-10 h.

6. The manufacturing process for a coiled graphene heat dissipation film material according to claim 1, wherein in step S6, the multi-layer rolling adopts a post-stacking rolling mechanism (4), the post-stacking rolling mechanism (4) comprises two to five traction rollers (41) and a coiling round roller (42), a speed of the traction rollers (41) is set to 1-5 m/min, a speed of the coiling round roller (42) is set to 1-5 m/min, and a coiling tension is controlled to 5-200 N.

7. The manufacturing process for a coiled graphene heat dissipation film material according to claim 1, wherein the tight coiled pretreated graphene film material (1) has a width of 10 cm-70 cm and a length of 30 m-200 m.

8. The manufacturing process for a coiled graphene heat dissipation film material according to claim 1, wherein a gap D between adjacent film layers in the loose coiled pretreated graphene film material (2) is two to nine times a thickness of the film layers.

9. The manufacturing process for a coiled graphene heat dissipation film material according to claim 1, wherein in the homogenization process of step S2, the homogenization pressure is 30-150 MPa, and the temperature is controlled at 10° C.-50° C.; and in the defoaming process, the degree of vacuum is maintained at 1 KPa-10 KPa.

10. The manufacturing process for a coiled graphene heat dissipation film material according to claim 1, wherein in step S6, the multi-layer rolling comprises an uncoiling stage, a first precision pressing stage, a second precision pressing stage, a third precision pressing stage, a fourth precision pressing stage, and a coiling stage; each of the uncoiling stage and the coiling stage is provided with a tension control unit and a tension amplifier; each of the first precision pressing stage, the second precision pressing stage, the third precision pressing stage, and the fourth precision pressing stage is provided with a pressure control unit, a pressure sensor, a linear speed control unit, and a speedometer; and the tension control unit, the pressure control unit, and the linear speed control unit are all connected to a PLC central processing unit.
